(19) United States
(12) Patent Application Publication
(10) Pub. No.: US 2002/0089391 A1
(43) Pub. Date: Jul. 11, 2002

(54) Method and apparatus for suppressing reception of weak navigation satellite signals

(76) Inventor: Kevin Dermot Miller, Tucson, AZ (US)

Correspondence Address: William A. Birdwell, BIRDWELL, JANKE & DURANDO, PLC, Suite 1925, 900 SW Fifth Avenue, Portland, OR, 97204, US

(21) Appl. No.: 09/755,916

(22) Filed: Jan. 5, 2001

(51) Int. Cl. H03H 7/00

(52) U.S. Cl. 333/12; 333/181

(57) ABSTRACT

A method and apparatus for suppressing weak navigation satellite signals so as to increase the continuity with which the location of the receiver can be determined. In a navigation satellite system having a receiver connected to an antenna or antennas by a shielded cable, a tubular member of magnetic material is placed around the outside of the cable, in close proximity to the receiver, in order to reduce the effect of relatively weak satellite signals that cannot be used, but interfere with the proper use of stronger signals.

### BACKGROUND OF THE INVENTION

This invention relates to the use of navigation satellite signals to locate the position of a navigation satellite receiver, and particularly to suppressing reception of weak navigation satellite signals so as to increase the continuity with which the location of the receiver can be determined.

Satellite navigation systems, such as the Global Positioning System (“GPS”) installed by the United States of America, and the Global Navigation Satellite Systems (“GLONASS”), installed by the Russian Federation, provide the location in space of a satellite signal navigation receiver in three dimensions—that is, longitude, latitude and altitude. They are used not only on ships and airplanes, but in many other diverse activities where location determination is important. One such activity is in the open-pit mining industry, where accurate, continuous determination of the elevation (z), as well as the lateral position (x, y), of a unit of mining equipment in an open-pit mine is essential to ensuring that, as the equipment removes minerals and moves from one location to the next, it properly tracks the pockets of minerals to be mined.

Basically, satellite navigation systems operate on a triangulation principle, whereby signals received by a satellite navigation system receiver from at least four satellites provide sufficient information for the receiver to identify its location. Three of the satellite signals must provide the identity of the respective locations of those satellites. One of the satellite signals must provide a timing signal to which the other three signals must be referenced. By measuring the time it takes three of the signals to reach the receiver, and with knowledge of the location of those three satellites, the location in space of the receiver can be determined. While at least four satellite signals are required, greater accuracy in locating the receiver may be achieved with more than four satellite signals, if they provide a signal of adequate strength continuously for the period of time necessary to process those signals.

In an open-pit mine, the number of satellite signals that can be received at a time is often limited by the relatively narrow field of view that the antenna or antennas on a unit of mining equipment have of the sky. Nonetheless, several more than four strong, line-of-site signals can often be received so that reasonably high accuracy of position can be determined.

What is most important to open-pit mining operations in the use of a satellite navigation system is the continuous availability of a set of satellite signals sufficient to determine the elevation of a mining equipment unit as the unit moves from location to location, removing minerals from the mine. While it would be convenient to know the absolute elevation with a high degree of accuracy, this is difficult to do with a satellite navigation system because the field of view of the antenna or antennas on a mining equipment unit is relatively narrow, so that the satellites that can be seen by the antenna or antennas are relatively close together. This limits the elevation accuracy that can be achieved. However, it is very important to know, on a real-time basis, whether the altitude of the unit has changed from one moment to the next.

It has been discovered that, ironically, sometimes the presence of a weak navigation satellite signal whose strength is not great enough to contribute to determination of the receiver location actually interferes with reception of strong satellite signals, causing the receiver frequently to vary the number of satellite signals that it is tracking, thereby delaying the position information and varying the accuracy with which it is delivered. This happens often enough that it is a significant problem in the open-pit mining industry.

Ferrite “beads” or “chokes” are commonly used to reduce radio frequency or electromagnetic interference (“RFI/EMI”) with electronic circuits. These are tubular members, typically cylindrical in shape, made of ferrite that are placed around a signal cable to introduce inductance and thereby create a low-pass filter. Such devices are disclosed, for example, in France, Jr., U.S. Pat. No. 5,990,756; Parker, U.S. Pat. No. 5,095,296; and Vince, U.S. Pat. No. 5,068,631. These applications operate on the principle that interference is being caused by frequencies significantly higher than those of the signal to be transmitted so that, by introducing a low-pass filter, the signal will pass, but the unwanted higher frequencies will not pass, the ferrite bead. However, all of the navigation satellite signal frequencies are supposed to be available for use, so the insertion of a low pass filter that would pass some, but block others would not only be seemingly random in effect, since there is no relationship between signal frequency and whether the signal is weaker than others, but would entirely prevent the use of some satellites. Therefore, such ferrite bead devices would logically seem to offer no help in solving the aforementioned problem.

Accordingly, there has been a heretofore unfulfilled need for some inexpensive and simple method and means to suppress the reception of weak navigation satellite signals.

### SUMMARY OF THE INVENTION

It has been discovered that the aforementioned problem can be alleviated by placement of a tubular piece of magnetic material adjacent to the satellite signal receiver input port and around the shielded transmission line that connects the satellite navigation signal antenna to the receiver. Preferably, the piece of magnetic material is a ferrite bead, that is, ferrite material, cylindrical in shape and radially sectioned so that it can be placed around the cable, in close proximity to the receiver, despite the existence of cable connectors on the ends thereof and even when the cable is already installed.

Accordingly, it is a principal object of the present invention to provide a novel and improved method for suppressing interference from weak navigation satellite signals so as to increase the continuity with which the location of the receiver can be determined.

It is another object of the present invention to provide a simple and inexpensive solution to the problem of suppressing reception of weak navigation satellite signals.

It is a further object of the present invention to provide a solution to the problem of suppressing the reception of weak navigation satellite signals that can be implemented in the field.

The foregoing and other objects, features and advantages of the present invention will be more readily understood upon consideration of the following detailed description of the invention, taken in conjunction with the accompanying drawings.

### BRIEF DESCRIPTION OF THE DRAWINGS

FIG. 1 is an illustration of a satellite navigation system in use by an open-pit mining operation.

FIG. 2 is a graph showing a typical sequence of satellite signal availability as various satellites move through the field of view of the antenna of a satellite navigation receiver in the presence of weak satellite signals.

FIG. 3 is a perspective drawing of a ferrite bead installed on a cable connected between a satellite navigation signal antenna and a satellite navigation signal receiver according to the present invention.

FIG. 4 is a perspective drawing of a radially segmented ferrite bead according to the present invention.

FIG. 5 is a graph showing a sequence of satellite signal availability as various satellites move through the field of view of a satellite navigation receiver antenna when a weak signal suppression member has been installed.

### DETAILED DESCRIPTION OF THE INVENTION

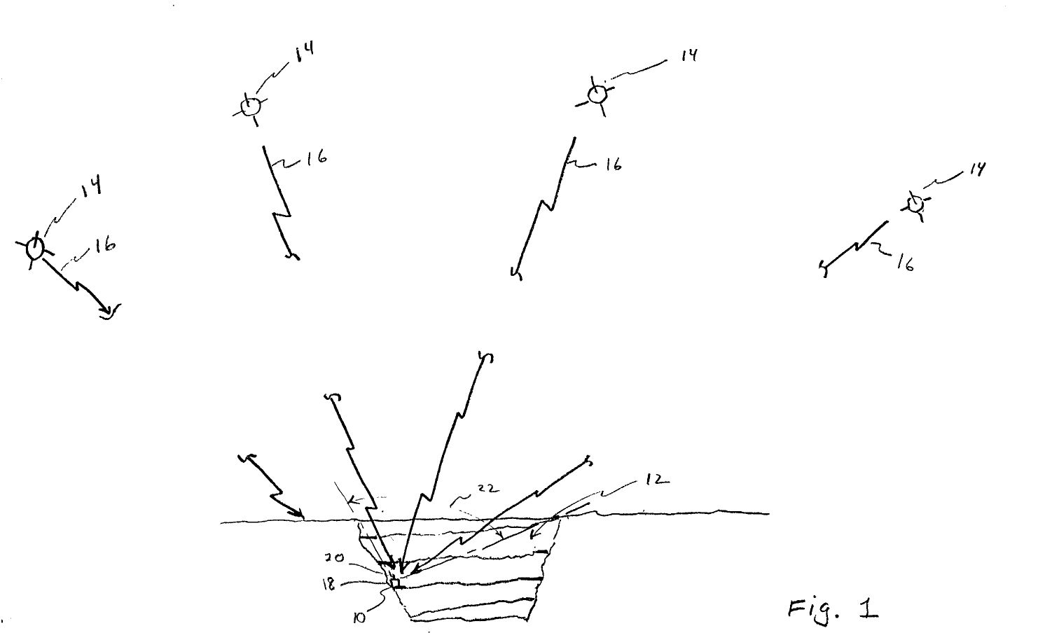

Referring first to FIG. 1, a mining equipment unit 10, such as a mechanized shovel, used in an open-pit mine 12 employs a satellite navigation system to determine its location, particularly its elevation or altitude. The satellite navigation system comprises a plurality of satellites 14 in earth orbit which broadcast navigation signals 16 toward the earth, and a satellite navigation signal receiver 18, having at least one antenna 20, mounted on the mining equipment for receiving the broadcast navigation signals and computing the location of the equipment. To that end, the navigation signals are encoded to identify the satellite from which they are broadcast and the location of that satellite, and to provide periodic pulses for gauging the distance of the satellite to the receiver.

Operation of the satellite navigation system requires that at least four different satellite signals be received by the receiver, one each for the latitude, longitude and altitude of the receiver, and one for a timing reference. Additional satellite signals can, but do not necessarily, produce greater accuracy in determining the position of the receiver, depending on the separation and position of the satellites. However, the number of satellite signals that can be received is limited by the field of view 22 of the antenna or antennas 20. Moreover, signals which are low in the horizon are more likely to be weak or distorted as a consequence of diffraction of the signal beam due to the proximity of objects on the surface of the earth and the edge of the mine pit. Weak and distorted signals tend to produce bad data and erroneous position measurements.

Each time the number of satellites being tracked by a receiver changes, the receiver must restructure the computation of position. For each satellite signal being tracked there is a corresponding variable whose value is unknown: a distance or a time. Each unknown requires a corresponding equation in a system of equations to be solved simultaneously to calculate receiver position. When the number of satellites being tracked changes, convergence to a solution of the new set of equations often takes a long time relative to convergence to a solution when the position of the receiver merely changes. This time may be as long as forty-five minutes, which is an unacceptable time period for the position of the mining equipment unit not to be known.

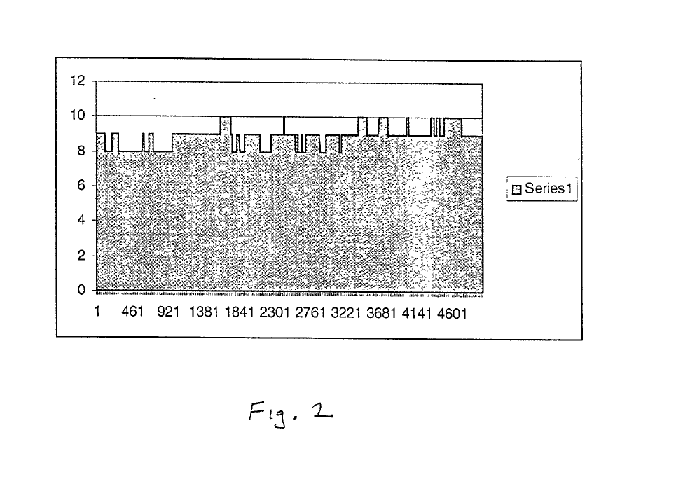

The graph of FIG. 2 illustrates a problem resulting from the aforedescribed characteristic. In that graph, the vertical axis represents the number of satellites being tracked by the receiver in a mining equipment unit, and the horizontal axis represents time, while the unit is actually stationary. The frequent changes in the number of satellites being tracked over time is a consequence of changes in the number of signals being received. It has been found that such frequent changes result from the presence of weak satellite signals that fade in and out so as to present varying numbers of satellite signals to the receiver over short periods of time. Consequently, the apparent elevation of the unit changes, even when the unit is stationary, and there are long periods during which there is no current elevation data.

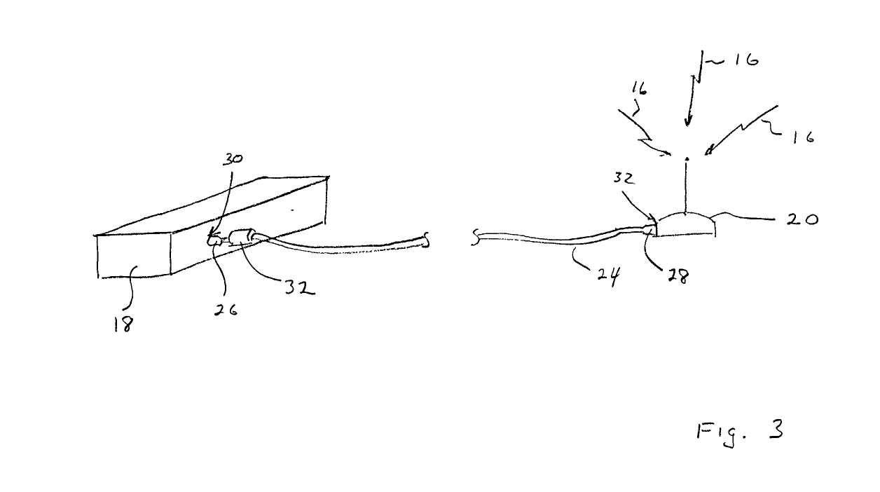

FIG. 3 illustrates the present invention, which is the solution to the aforedescribed problem. In FIG. 3, a satellite navigation signal receiver 18 is connected to its antenna 20 by a shielded cable 24. Typically, the shielded cable is commonly-used 50 ohm coaxial cable with a braided shield, though other types of shielded cable may be used. Typically, the two ends of the cable 24 are fitted with coaxial connectors 26 and 28 which connect the cable to the input port 30 of the receiver and the output port 32 of the antenna, respectively, as is commonly understood in the art.

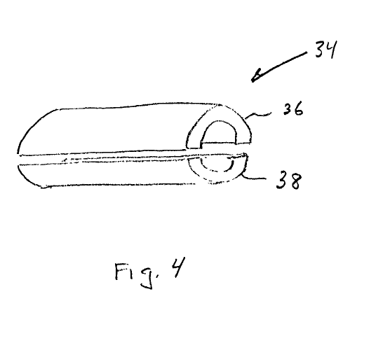

According to the present invention, a tubular interference suppression member 32, comprised of magnetic material, is placed around the cable 24 adjacent to the input port 30 of the receiver. Preferably, the material is ferrite material. Preferably also, the tubular member is in the shape of a cylinder. For retro-fitting a cable, the member is preferably a cylindrical tube 34 radially segmented into two mating parts 36 and 38, as shown in FIG. 4, so that it may placed around the cable despite the existence of connectors 26 and 28, and despite prior installation of the cable into a satellite navigation system, which may even be in operation. It is to be recognized, however, that other magnetic materials, other tubular shapes and a greater number of segments may be used without departing from the principles of the invention, so long as they have equivalent effect, as described hereafter.

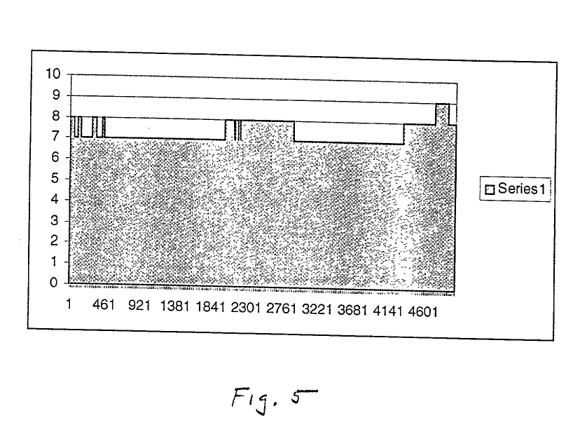

Once the suppression member is installed, the frequency of changes in the number of satellites being tracked drops substantially, as shown by FIG. 5. In that figure, the vertical axis represents the number of satellites being tracked by the receiver, and the horizontal axis represents time. The mining equipment unit is stationary. As can be seen by comparing FIG. 5 to FIG. 3, the frequency of changes is much lower with the suppression member installed. So, while the accuracy may, but is not necessarily reduced, the continuity is maintained for longer periods.

The terms and expressions which have been employed in the foregoing specification are used therein as terms of description and not of limitation, and there is no intention, in the use of such terms and expressions, of excluding equivalents of the features shown and described or portions thereof, it being recognized that the scope of the invention is defined and limited only by the claims which follow.

1. A method for suppressing weak navigation satellite signals, comprising:
providing a navigation satellite signal receiver having an antenna input port;
providing a navigation satellite signal antenna having an output port;
connecting said antenna output port to said receiver input port with a shielded cable; and
placing around said shielded cable adjacent to said input port a tubular suppression member whose composition comprises magnetic material.

2. The method of claim 1, wherein said composition of said suppression member comprises ferrite material.

3. The method of claim 1, wherein said suppression member is cylindrical in shape.

4. The method of claim 3, wherein said suppression member comprises a plurality of radially-mating parts, said parts being matingly placed over said cable after said cable is connected.

5. An apparatus for suppressing weak navigation satellite signals by a navigation satellite signal receiver having an antenna input port for connection to a navigation satellite signal antenna having an output port, comprising:
a shielded cable for connection between the output port of the antenna and the input port of the navigation satellite receiver; and
a tubular suppression member for placement around said shielded cable, the composition of said suppression member comprising magnetic material.

6. The apparatus of claim 5, wherein said composition of said suppression member comprises ferrite material.

7. The apparatus of claim 6, wherein said suppression member is cylindrical in shape.

8. The apparatus of claim 5, wherein said suppression member comprises a plurality of radially-mating parts, said parts being matingly placed over said cable after said cable is connected.
